(19) United States
(12) Patent Application Publication
(10) Pub. No.: US 2009/0211631 A1
(43) Pub. Date: Aug. 27, 2009

(54) PHOTOLUMINESCENT BACKING SHEET FOR PHOTOVOLTAIC MODULES

(76) Inventors: Marina Temchenko, Swampscott, MA (US); David William Avison, Townsend, MA (US); Frank Anthony Mannarino, Medway, MA (US); Samuel Lim, Lynn, MA (US)

Correspondence Address: NORRIS MCLAUGHLIN & MARCUS, P.A., 721 ROUTE 202-206, P.O.BOX 5933, BRIDGEWATER, NJ, 08807-5933, US

(21) Appl. No.: 12/345,954

(22) Filed: Dec. 30, 2008

Related U.S. Application Data
(60) Provisional application No. 61/009,978, filed on Jan. 3, 2008.

(51) Int. Cl. H01L 31/00

(52) U.S. Cl. 136/256

(57) ABSTRACT

The present invention provides a protective backing sheet for photovoltaic modules. The backing sheets are capable of absorbing a wide range of solar wavelengths (UV, IR and visible) and re-emitting the absorbed solar radiation as a photons wherein the energy is at or greater than the band gap energy of corresponding semiconductor. The backing sheet can be used in a variety of applications including in photovoltaic devices.

### CROSS REFERENCE TO RELATED APPLICATION

This application claims the benefit of U.S. Provisional Patent Application No. 61/009,978, filed Jan. 30, 2008, the entirety of which is hereby incorporated by reference into this application.

### BACKGROUND OF THE INVENTION

1. Field of the Invention

The present invention relates to photovoltaic modules. More specifically the present invention related to the protective backing sheets.

2. Description of Related Art

Solar energy utilized by photovoltaic modules is among the most promising alternatives to the fossil fuel that is being exhausted this century. However, production and installation of the photovoltaic modules remains an expensive process. Typical photovoltaic modules consist of glass or flexible transparent front sheet, solar cells, encapsulant, protective backing sheet, a protective seal which covers the edges of the module, and a perimeter frame made of aluminum which covers the seal. As illustrated in FIG. 1, a front sheet 10, backing sheet 20 and encapsulant 30 and 30′ are designed to protect array of cells 40 from weather agents, humidity, mechanical loads and impacts. Also, they provide electrical isolation for people's safety and loss of current. Protective backing sheets 20 are intended to improve the lifecycle and efficiency of the photovoltaic modules, thus reducing the cost per watt of the photovoltaic electricity. While the front sheet 10 and encapsulant 30 and 30′ must be transparent for high light transmission, the backing sheet must have high opacity for aesthetical purposes and high reflectivity for functional purposes. Light and thin solar cell modules are desirable for a number of reasons including weight reduction, especially for architectural (building integrated PV) and space applications, as well as military applications (incorporated into the soldier outfit, etc). Additionally light and thin modules contribute to cost reduction. Also reduction in quantity of consumed materials makes the technology “greener”, thus saving more natural resources.

On means to manufacture light and thin solar cells is to incorporate light and thin backing sheets. The backside covering material however, must also have high moisture resistance to prevent permeation of moisture vapor and water, which can cause rusting in underlying parts such as the photovoltaic element, wire, and electrodes, and damage solar cells. In addition, backing sheets should provide electrical isolation, mechanical protection, UV protection, adherence to the encapsulant and ability to attach output leads.

Currently used protective backing sheets are typically laminates. FIG. 2 provides an illustration of a typical laminate backing sheet 20. The laminate consists of films of polyvinylfluorides 22, which is most commonly Tedlar®, polyesters (PET) 24, and copolymers of ethylene vinyl acetate (EVA) 26 as key components. The EVA layer 26 bonds with the encapsulant layer 30 in the module and serves as a dielectric layer and has good moisture barrier properties. It is dimensionally stable. White EVA allows for some power boost. The polyester layer 24 is very tough, has excellent dielectric properties, is dimensionally stable, and also has good moisture barrier properties. The polyvinylfluoride layer 22 serves as a very weatherable layer.

Photovoltaic (PV) devices are characterized by the efficiency with which they can convert incident solar power to useful electric power. Devices utilizing crystalline or amorphous silicon have achieved efficiencies of 23% or greater. However, efficient crystalline-based devices are difficult and expensive to produce. In order to produce low-cost power, a solar cell must operate at high efficiency.

A number of techniques have been proposed for increasing the efficiency and effectiveness of PV modules. One approach is to enhance light reflection by a protective back sheet for the solar cell.

Prior art techniques are time consuming and expensive. For example, one approach proposes utilizing a back sheet with a plurality of V-shaped grooves that provide angular light reflecting facets. Such textured material is produced in several steps. First, the film that serves as the substrate is manufactured as a continuous or extended web having flat front and back surfaces, and that continuous web is then wound onto a roll for subsequent processing. Further processing includes first embossing the film so as to form V-shaped grooves on one side, and then metalizing the grooved surface of the film. The film is heated so that, as it passes between the two rollers, it is soft enough to be shaped by the ridges on the embossing roller. After formation of grooves, the plastic film is subjected to a metalizing process wherein an adherent metal film is formed. The metalized film is wound on a roll for subsequent use as a light reflector means.

### SUMMARY OF THE INVENTION

The present invention provides a protective backing sheet for photovoltaic modules. The backing sheets are capable of absorbing a wide range of solar wavelengths (UV, IR and visible) and re-emitting the absorbed solar radiation as a photons wherein the energy is at, or greater than, the band gap energy of corresponding semiconductor. The backing sheets provide higher reflectance and power output by increasing reflectivity of all layers of multilayer construction. The backing sheet can be used in a variety of applications including in photovoltaic devices.

In one embodiment, a backing sheet for a photovoltaic module is provided comprising a polymer layer with one or more white pigments and one or more photo luminescent materials. The polymer layer may contain about 20 to 60 weight percent of white pigments. The photoluminescent materials have the capacity to absorb UV light and re-emit it as a visible light. The photoluminescent material may be, for example, an optical brightener.

The backing sheet may further comprise a first outer layer of weatherable film.

In another embodiment the backing sheet may also include one or more layers of polyester, EVA, polybutadiene, polyacrylate, polyimide, latex, magnesium fluoride, parylene, heat dissipating materials, polycarbonate, polyolefin, polyurethane, liquid crystal polymer, aclar, aluminum, sputtered aluminum oxide polyester, sputtered silicon ioxide/silicon nitride polyester, sputtered aluminum oxide polycarbonate, and sputtered silicon oxide/silicon nitride polycarbonate, sputtered aluminum oxide fluorocopolymer with crosslinkable functional groups, sputtered silicon oxide/silicon nitride fluorocopolymer with crosslinkable functional groups.

In another embodiment a method of boosting the power of a photovoltaic module that has a backing sheet is provided. The method includes incorporation of one or more white pigments and one or more photo luminescent materials to at least a portion, or to all layers, of the backing sheet facing the photovoltaic cells.

In another embodiment a method of boosting the power of a photovoltaic module that has a backing sheet is provided. The method includes applying a coating comprising one or more white pigments and one or more photo luminescent materials to at least a portion, or to all layers, of the backing sheet facing the photovoltaic cells.

In another embodiment a method of boosting the power of a photovoltaic module that has a backing sheet is provided. The method includes applying a coating comprising one or more white pigments and one or more non-linear optic materials to at least a portion, or to all layers, of the backing sheet facing the photovoltaic cells.

In another embodiment a method of boosting the power of a photovoltaic module that has a backing sheet is provided. The method includes incorporation of one or more white pigments and one or more non-linear optic materials to at least a portion, or to all layers, of the backing sheet facing the photovoltaic cells.

### BRIEF DESCRIPTION OF THE DRAWINGS

For a better understanding of the present invention, reference may be made to the accompanying drawings.

FIG. 1 represents an expanded view of the components of a typical photovoltaic module.

FIG. 2 represents one embodiment of the typical backing sheet.

FIG. 3 is a graph showing typical excitation and photoluminescence spectra of manufactured photoluminescent materials.

FIG. 4 is a graph showing the effect of the addition of optical brightener to a pigmented resin on the efficiency of the solar panel.

FIG. 5 is a graph showing the effect of addition of optical brightener to a pigmented resin on the Pmax of the solar panel.

FIG. 6 is a graph showing typical curve of current vs voltage characteristic (I-V) of solar cells and modules.

FIG. 7 is a graph showing the effect of addition of optical brightener to a pigmented coating on the Isc of the solar panel.

FIG. 8 is a graph showing the effect of addition of optical brightener to a pigmented coating on the Pmax of the solar panel.

FIG. 9 is a graph showing the reflectance at 440 nm for a conventional 3 layer backsheet construction for 6 different product constructions all utilizing the same white EVA inner layer.

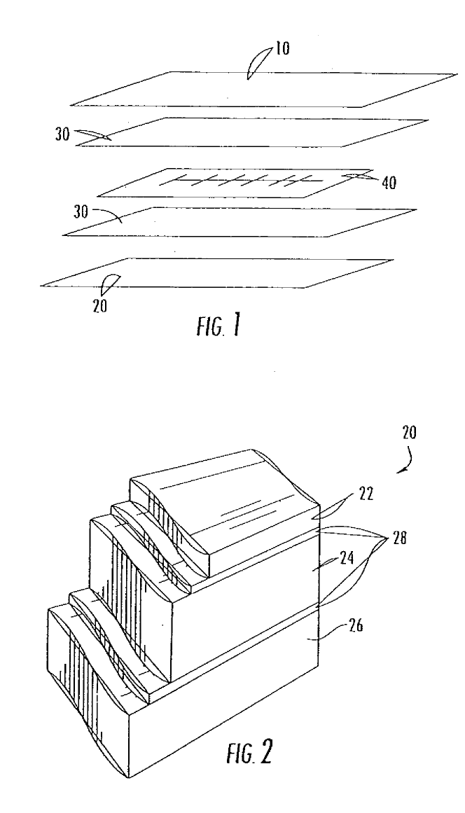

### DETAILED DESCRIPTION

### Overview

The present invention provides a protective backing sheet for photovoltaic modules. The backing sheets are capable of absorbing a wide range of solar wavelengths (UV, IR and visible) and re-emitting the absorbed solar radiation as a photons wherein the energy is at or greater than the band gap energy of corresponding semiconductor. The backing sheet can be used in a variety of applications including in photovoltaic devices.

The “photovoltaic effect” is the basic physical process through which a PV cell converts sunlight into electricity. Sunlight is composed of photons, or particles of solar energy. These photons contain various amounts of energy corresponding to the different wavelengths of the solar spectrum. When photons strike a PV cell, they may be reflected or absorbed, or they may pass right through. Only the absorbed photons with the energy at or higher than the band gap of the semiconductor can generate electricity. When this happens, the energy of the photon is transferred to an electron in an atom of the cell (semiconductor). Photons which are passed through the cell or between the cells are absorbed by the backing sheet and re-emitted. The re-emitted light from the backing sheet is directed back to the solar cell where it is converted by the semiconductor material into the electric current. As a result, the backing sheet of the present invention, when used as a protective backing sheet for PV modules, results in a power boost efficiency increase compared to the ordinary backing sheets.

Backing Sheets

The backing sheet of the present invention can be made of any material, usually polymers, typically used to produce backing sheet. In one embodiment, the combination of one or more white pigments and one or more photo luminescent materials is incorporated into a polymer matrix to form a film or sheet. In another embodiment, backing sheet is prepared by applying a coating containing one or more white pigments and one or more photoluminescent materials to a polymer film. Numerous arrangements are possible. The key property of the backing sheet is that perform function of absorbing solar radiation of various wavelengths and converting the absorbed solar radiation into photons with energy at or greater than the band gap energy of corresponding semiconductor. As discussed further below, this is easily and simply accomplished in one embodiment by using a combination of white pigments and photo luminescent materials into one or more layers of the backing sheet.

In one embodiment, the inventive backing sheet contains additional optional layers and is formed into a laminate. The laminate can be used, for example, in electronic devices such as photovoltaic (PV) modules. When used as protective backing sheets for PV modules, laminates result in an increase of the power output of the module, remain aesthetically satisfactory over extended use, provide effective protection for the current generated in the PV module and exhibit high dielectric strength.

In one embodiment the laminate comprises (a) a first outer layer of weatherable film; (b) at least one mid-layer; and (c) a second outer layer (alternatively referred to as an inner layer or photoluminescent layer) which is capable of absorbing a wide range of solar wavelengths (UV, IR and visible) and converting the absorbed solar radiation into photons whose energy is at or greater than the band gap energy of corresponding semiconductor When used in a photovoltaic module, the first outer layer of the laminate is exposed to the environment, and the inner layer is exposed to or faces the solar cells and solar radiation.

In an alternate embodiment, the composite reflectance of the laminate is increased by including more than one layer capable of absorbing solar radiation of various wavelengths and converting the absorbed solar radiation into photons with energy at or greater than the band gap energy of corresponding semiconductor. For example, in the laminate describe above, the first outer layer and/or mid layer are also incorporated with one or more white pigments and one or more photo luminescent materials in the same manner as the inner layer as discussed below. Such an arrangement results in a greater increase in net reflectance and greater module efficiency/power output.

The individual layers of the laminates of the present invention can be adhesively bonded together. The specific means of forming the laminates of the present invention will vary according to the composition of the layers and the desired properties of the resulting laminate, as well as the end use of the laminate.

The inner layer or photoluminescent layer can be made of any material, but is typically made of one or more polymers. In one example, inner layer is made of ethylene vinyl acetate (EVA). The vinyl acetate content of the EVA is generally about from 2 to 33 weight percent and preferably from 2 to 8 weight percent. The combination of white pigments and photo luminescent materials are incorporated into the EVA (or other polymer) matrix to achieve the desired photoluminescence.

Any white pigment may be used. For example, titanium dioxide, (Ti-Pure® series of titanium dioxide made by DuPont for example), calcium carbonate, lithopone, zinc sulfate, aluminum oxide, boron nitride, etc. can be used depending on the application. Again, depending on the application, the white pigment is typically added at to the polymer of the inner layer to contain about 20-60 weight percent. Of these, titanium dioxide is preferred for its ready availability.

Preferably, photo luminescent materials are added to the inner layer in combination with the white pigment but can be added without the pigment and/or can be added to more than one layer of the laminate or all layers of backing sheet. The addition of photo luminescent material to multiple layers increases the net reflectance of the laminate. Photoluminescence is the complete process of absorption and re-emission of light. Ordinary pigments absorb and reflect energy, while photoluminescent materials absorb, reflect and re-emit. They are typically added to the inner layer to contain about 0.01-30.0 weight %.

One example of photoluminescent materials is optical brighteners. Optical brighteners fluoresce and are particularly preferred for use in the backing sheet. Optical brighteners, such as Ciba® UVITEX® OB, absorb UV light and re-emit it as a visible light. For different semiconductors with different energy gaps, other photoluminescent materials with matching characteristics are easily identified and incorporated into the backing sheet.

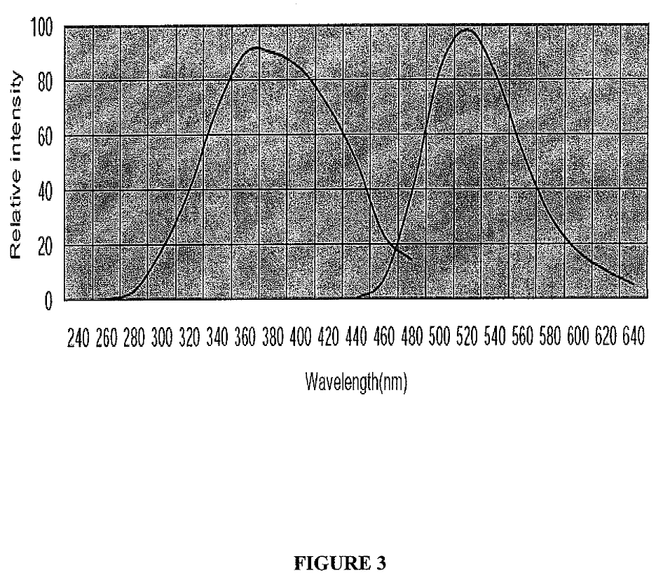

Another example of photoluminescent materials are BASF manufactured dyes (coumarine and perylene based) or Lightleader Co., Ltd manufactured materials. For example, YG-1F. A typical excitation (left) and photoluminescence spectra (right) is depicted in FIG. 3. Alternatively non linear optic materials such as metal fluoride phosphors may be used. These phosphors may be used for upcoversion of infrared (IR) radiation to various forms of visible light.

In yet another embodiment, the inner layer inner layer or photoluminescent layer is matrix of an organic solvent soluble and/or water dispersible, crosslinkable amorphous fluoropolymers containing white pigments and photo luminescent materials. Particular embodiments include a copolymer of tetrafluoroethylene (TFE) and hydrocarbon olefins with reactive OH functionality. The layer may further include a crosslinking agent mixed with the fluorocopolymer.

Crosslinking agents are used in the formation of the protective coatings include to obtain organic solvent insoluble, tack-free film. Preferred crosslinking agents include but are not limited to DuPont Tyzor® organic titanates, silanes, isocyanates, melamine, etc. Aliphatic isocyanates are preferred to ensure weatherability as these films are typically intended for over 30 years use outdoor.

In an alternate embodiment, white pigmented polyvinyl fluoride (such as that commercially available from DuPont as Tedlar® polyvinyl fluoride) is used as the inner layer or photoluminescent layer. To achieve the desired photoluminescence, the layer is coated with thin light reflecting film containing photo luminescent materials, and optionally white pigment. Preferably, the white coating contains from 40 to 50 weight % of white pigment and 0.01-2.0 weight % fluorescent whitening agents.

The matrix for the thin light reflecting coating can be selected from a wide variety of polymers, such as acrylic polymers, urethane, polyesters, fluoropolymers, chlorofluoropolymers, epoxy polymers, polyimides, latex, thermoplastic elastomers, and ureas. The Thin light reflecting coating can be applied to the second outer layer by any of a variety of methods known to those skilled in the art of film coating manufacture. Preferred methods include coating application by spraying, dipping and brushing.

The photoluminescent coating can be applied to any backing sheet to impart the desired photoluminescence. That is, any backing sheet known in the art can be converted to a power boosting backing sheet by coating the backing sheet with a photoluminescent coating, preferably one that contains white pigment. A primary consideration in choosing the specific photoluminescent material is to match the peak emission wavelength (i.e., at or near) with a band gap of the semiconductor material within the intended photovoltaic device.

The backing sheet may also include additional layers. The additional layers may be applied to the fluorocopolymer layer with or without adhesive. The optional additional layers may include, for example, one or of a polyester, EVA, polycarbonate, polyolefin, polyurethane, liquid crystal polymer, aclar, aluminum, sputtered aluminum oxide polyester, sputtered silicon dioxide polyester, sputtered aluminum oxide polycarbonate, sputtered silicon dioxide polycarbonate, sputtered aluminum oxide fluorocopolymer with crosslinkable functional groups, sputtered silicon oxide fluorocopolymer with crosslinkable functional groups.

### EXAMPLE LAMINATES

Examples of laminates were prepared according to the present invention. In addition, comparative examples were also prepared. The examples were then subjected to a number of tests. The tests illustrate the advantages of the advantages of the inventive backing sheet.

Two laminates were prepared in accordance with the present invention as follows:

### Example 1

Example 1 is a three layer laminate with a first outer layer of Tedlar white with a thickness of 1.5 mil. The laminate has a middle layer of Polyester Mylar A with a thickness of 5 mils. The third layer is an inner photoluminescent layer. The photoluminescent layer is EVA with combination of white pigments and photo luminescent materials incorporated into the EVA. The thickness is 4 mils.

### Example 2

Example 2 is a three layer laminate where the first outer layer is the same as the layer in Example 1. The middle layer is Polyester Mylar A with a thickness of 3 mils. The inner layer is also Tedlar white with a thickness of 1.5 mils. The inner layer is coated with a coating containing a combination of white pigments and photo luminescent materials (Ciba® UVITEX® OB, 0.9-1 weight %). The coating is applied using Mayer Rod at a coat weight of 9 g/m.

Comparative Example 1 is a laminate that contains the same three layers as Example 1 except the inner layer only contains white pigments but does not contain the photoluminescent material.

Comparative Example 2 is a laminate that contains the same three layers as Example 2 except the coating on the inner layer only contains white pigments but does not contain photoluminescent material.

Solar Panels

The Example laminates and Comparative example laminates were vacuum laminated to EVA encapsulant. Two Solar panels SS80 utilizing 36 BP crystalline silicon cells (2-2.5 W each and 2 mm spacing) were used. Vacuum lamination was performed using SPI-LAMINATOR™ 480 (Spire) at a vacuum ˜500 millitorr and temperature 100° C. with pumping for 5 minutes and processing for 2 minutes.

The efficiency of hacking sheets for use in photovoltaic modules was evaluated by exposing solar panels to simulated sun light using multipulse SPI-SUN SIMULATOR 3500 Series (Spire). 11 measurements were taken for each back sheet and each solar panel. Isc, Voc, Pmax, FF and Efficiency were recorded.

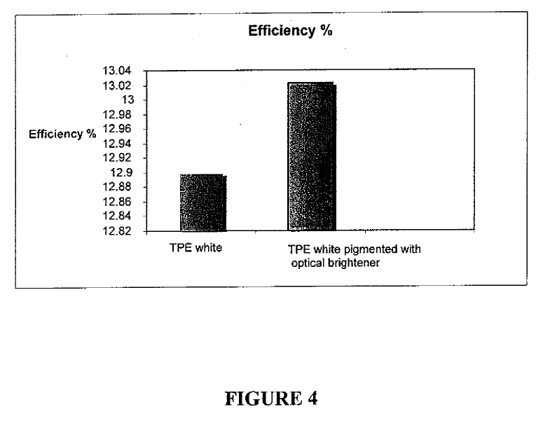

The results were charted and are depicted in FIGS. 4-8. FIG. 4 illustrates the effect of addition of optical brightener to the white pigmented EVA (referred to in FIGS. 4-5 and 7-8 as TPE white pigmented with optical brightener or Tedlar white pigmented with optical brightener). The addition of optical brightener results in a power boost (˜1 w) and 0.9% efficiency increase compared to the same pigmented films without optical brightener.

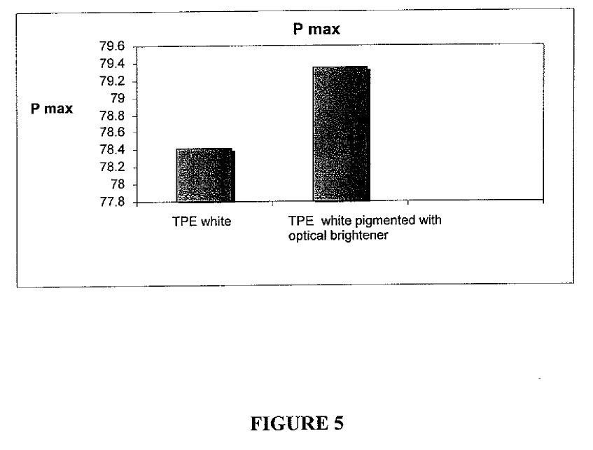

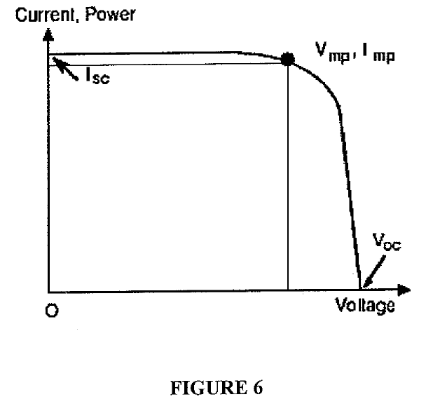

FIG. 5 illustrates the effect of addition of optical brightener to the pigmented resin on the P max of the solar panel ˜2% increase in short circuit current generation. The performance of solar cells and modules can be described by their current vs voltage characteristic (I-V). The typical I-V curve is presented in FIG. 6. The critical parameters on the I-V curve are the open circuit voltage (Voc), the short-circuit current (Isc) and the maximum power-point (Pmax). Isc, the maximum current at zero voltage, is directly proportional to the available sunlight. Voc can be determined from a linear fit to the I-V curve around the zero current point. Pmax is an electrical output when operated at a point where the product of current and voltage is at maximum.

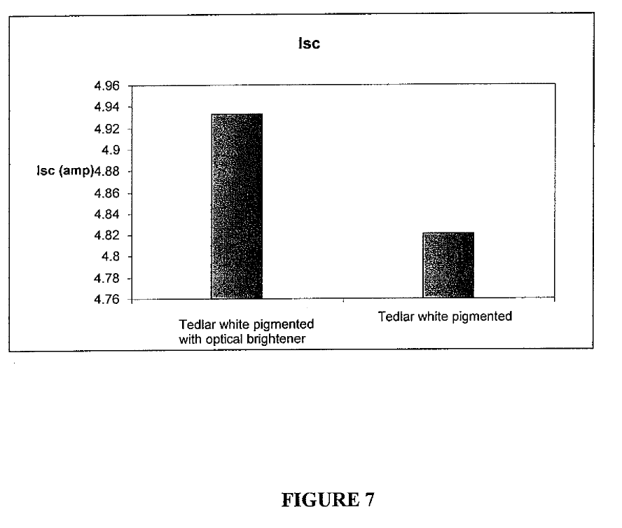

FIG. 7 illustrates the effect of addition of optical brightener to the pigmented coating on the Isc of the solar panel. The left column represents the Isc of Example 2 and the right column represents the Isc of comparative Example 2.

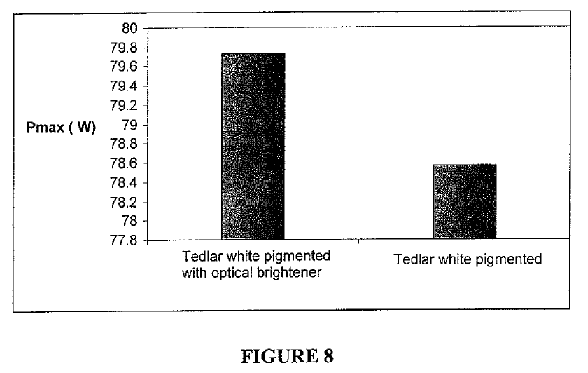

FIG. 8 illustrates the Effect of addition of optical brightener to the pigmented coating on the Pmax of the solar panel. The left column represents the Pmax of Example 2 and the right column represents the Pmax of comparative Example 2.

Testing of the modules for electrical power output was conducted by illuminating each module with a solar simulator light source and measuring the short-circuit current (Isc), open-circuit voltage (Voc), maximum power-point (Pmax), and the power conversion efficiency, η.

Pmax is an electrical output when operated at a point where the product of current and voltage is at maximum.

Pmax=ImpVmp.

The power conversion efficiency, η, is defined as

$$η = \frac{P max}{Pin} = \frac{FFVocIsc}{Pin}$$

where Pin is an incident radiant power; it is determined by the properties of the light spectrum incident upon the solar cell.

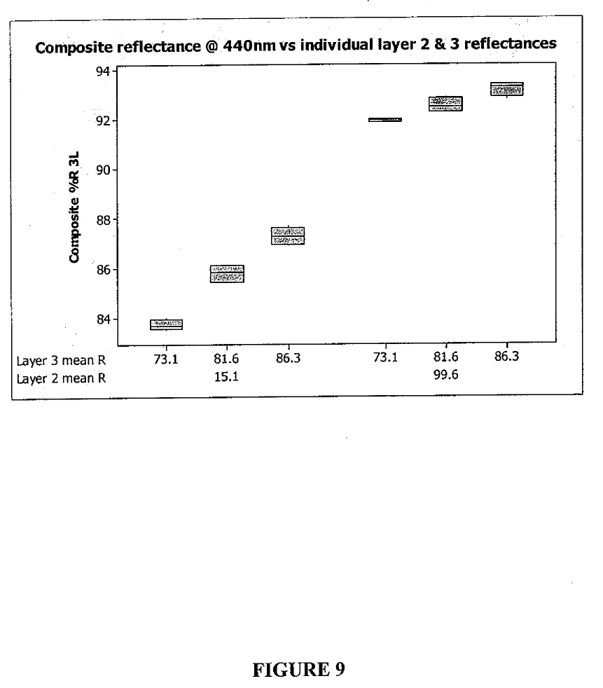

FIG. 9 illustrates that by increasing the reflectivity of more than one layer or all layers, including outer layer not facing solar cells, results in an net reflectivity increase and consequently in the increase of power output of the cell. This graph shows the range of reflectance values at 440 nm for 6 different product constructions all utilizing the same white EVA inner layer but different mid-layers and outer layers.

The three boxes on the left side represent back-sheet constructions produced using 3 different white outer layers (which individual reflectances are specified at the bottom of the graph as “Layer 3 mean R”) and a clear PET mid-layer (“Layer 2”) whose individual reflectance is ˜15%. The composite reflectance in dependent on the outer layer reflectance.

Replacing the clear PET mid layer (Layer 2) with an opaque, reflective mid layer (mean reflectance 99.6%) results in a dramatic increase in the composite backsheet reflectance. These are shown in the three boxes on the right of the graph.

There will be various modifications, adjustments, and applications of the disclosed invention that will be apparent to those of skill in the art, and the present application is intended to cover such embodiments. Although the present invention has been described in the context of certain preferred embodiments, it is intended that the full scope of these be measured by reference to the scope of the following claims.

The disclosures of various publications, patents and patent applications that are cited herein are incorporated by reference in their entireties.

What is claimed is:

1. A backing sheet for a photovoltaic module comprising:
a polymer layer comprising one or more white pigments and one or more photo luminescent materials.

2. The backing sheet of claim 1 wherein the polymer layer comprises about 20 to 60 weight percent of white pigments.

3. The backing sheet of claim 1 wherein the white pigment comprise one or more of titanium dioxide, calcium carbonate, lithopone, and zinc sulfate.

4. The backing sheet of claim 1 further comprising a first outer layer of weatherable film.

5. The backing sheet of claim 4 further comprising one or more layers chosen from the group of a polyester, EVA, polycarbonate, polyolefin, polyurethane, liquid crystal polymer, aclar, aluminum, sputtered aluminum oxide polyester, sputtered silicon dioxide polyester, sputtered aluminum oxide polycarbonate, and sputtered silicon dioxide polycarbonate, sputtered aluminum oxide fluorocopolymer with crosslinkable functional groups, sputtered silicon oxide fluorocopolymer with crosslinkable functional groups.

6. The backing sheet of claim 1 wherein the photo luminescent materials absorb UV light and re-emit it as a visible light.

7. The backing sheet of claim 6 wherein the photoluminescent material is an optical brightener.

8. The backing sheet of claim 1 wherein the polymer layer comprises an organic solvent soluble and/or water dispersible, crosslinkable amorphous fluoropolymers.

9. The backing sheet of claim 8 where the fluoropolymer is a fluorocopolymer of chlorotrifluoroethylene (CTFE) and one or more alkyl vinyl ethers

10. The backing sheet of claim 1 wherein the polymer layer further comprises a light reflecting coating on the outer surface thereof.

11. The backing sheet of claim 5 wherein one or more of the additional layers comprise one or more white pigments and one or more photo luminescent materials.

12. A photovoltaic module comprising:
a backing sheet comprising one or more white pigments and one or more photo luminescent material, wherein the backing sheet is capable of absorbing solar radiation and converting the absorbed solar radiation into a peak emission wavelength; and
one or more semiconductors comprised of a material with a band gap at or near the peak emission wavelength.

13. The photovoltaic module of claim 12 wherein the backing sheet comprises a polymer layer comprising about 20 to 60 weight percent of white pigments.

14. The photovoltaic module of claim 13 wherein the white pigment comprise one or more of titanium dioxide, calcium carbonate, lithopone, and zinc sulfate.

15. The photovoltaic module of claim 12 wherein the backing sheet further comprises a first outer layer of weatherable film.

16. The photovoltaic module of claim 12 wherein the backing sheet further comprises one or more layers chosen from the group of a polyester, EVA, polycarbonate, polyolefin, polyurethane, liquid crystal polymer, aclar, aluminum, sputtered aluminum oxide polyester, sputtered silicon dioxide polyester, sputtered aluminum oxide polycarbonate, sputtered silicon dioxide polycarbonate, sputtered aluminum oxide fluorocopolymer with crosslinkable functional groups, sputtered silicon oxide fluorocopolymer with crosslinkable functional groups.

17. The photovoltaic module of claim 12 wherein the photo luminescent materials absorb UV light and re-emit it as a visible light.

18. The photovoltaic module of claim 12 wherein the photoluminescent material is an optical brightener.

19. The photovoltaic module of claim 13 wherein the polymer layer comprises an organic solvent soluble and/or water dispersible, crosslinkable amorphous fluoropolymers.

20. The photovoltaic module of claim 19 where the fluoropolymer is a fluorocopolymer of chlorotrifluoroethylene (CTFE) and one or more alkyl vinyl ethers

21. The photovoltaic module of claim 13 wherein the polymer layer further comprises a light reflecting coating on the outer surface thereof.

22. The photovoltaic module of claim 16 wherein one or more of the additional layers comprise one or more white pigments and one or more photo luminescent materials.

23. A method of boosting the power of a photovoltaic module with a backing sheet comprising:
applying a coating comprising one or more white pigments and one or more photo luminescent materials to a portion of the backing sheet facing the photovoltaic cells.
